(19) United States
(12) Patent Application Publication
(10) Pub. No.: US 2006/0156098 A1
(43) Pub. Date: Jul. 13, 2006

(54) Method and apparatus for testing an electronic device

(76) Inventors: Mahuammad Ali Bawany, Sachse, TX (US); Frederick Hartnett, McKinney, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/999,835

(22) Filed: Nov. 30, 2004

(51) Int. Cl. G01R 31/28

(52) U.S. Cl. 714/724

(57) ABSTRACT

An apparatus for testing an electronic device is provided. More specifically, there is provided a method comprising placing a first integrated circuit into a test mode, wherein the first integrated circuit is coupled to a conductive interconnect, causing a register assembly located on the first integrated circuit to transmit a test signal onto the conductive interconnect, and placing the register assembly into a neutral state, wherein the first integrated circuit is placed into the neutral state without exiting the test mode. An apparatus for performing the method is also provided.

### BACKGROUND

This section is intended to introduce the reader to various aspects of art, which may be related to various aspects of the present invention that are described or claimed below. This discussion is believed to be helpful in providing the reader with background information to facilitate a better understanding of the various aspects of the present invention. Accordingly, it should be understood that these statements are to be read in this light and not as admissions of prior art.

Modem electrical devices, such as computers, cell phones, and digital cameras, often employ a large number of integrated circuits, such as processors or memory chips. These integrated circuits are typically fastened to a printed circuit board (“PCB”), such as a computer motherboard, and are typically connected to other integrated circuits by conductive interconnects, such as wires or traces. If any of these conductive interconnects is either not connected or is connected incorrectly, it can cause the electrical device to malfunction. For this reason, testing these conductive interconnects is a high priority for the manufacturers of electrical devices.

One way to check for problems with the conductive interconnects is with a connectivity test. One type of connectivity test can be performed by transmitting (also known as driving) a test signal between registers located on integrated circuits disposed on either side of a particular one of the conductive interconnects. If the test signal arrives at the destination register intact, it may indicate that the conductive interconnect between the registers is functioning properly. The manufacturers of electronic devices may test many conductive interconnects simultaneously. Typically, this simultaneous testing involves testing all of the conductive interconnects along a serial electrical path that runs amongst a plurality of integrated circuits. This serial path is known as a scan chain. Because modern PCBs are typically quite complex, most modern PCBs employ a series of different scan chains to perform a series of connectivity tests. Performing this series of connectivity tests, however, may have potential disadvantages. In particular, if one of the registers is driving a test signal onto one of the conductive interconnects as part of one connectivity test at the same time that second register is driving second test signal onto the same conductive interconnect as part of a second connectivity test, it can damage the PCB or circuit components. This scenario is referred to as a drive fight.

### BRIEF DESCRIPTION OF THE DRAWINGS

FIG. 1 is a block diagram illustrating an exemplary system configured to perform connectivity tests in accordance with embodiments of the present invention;

FIG. 2 is a block diagram illustrating two exemplary integrated circuits and a scan controller configured to perform connectivity tests in accordance with embodiments of the present invention;

FIG. 3 is a block diagram illustrating an exemplary register assembly and input/output pin configured to perform connectivity tests in accordance with embodiments of the present invention; and

FIG. 4 is a flow chart illustrating an exemplary process for performing connectivity tests in accordance with embodiments of the present invention.

### DETAILED DESCRIPTION OF SPECIFIC EMBODIMENTS

One or more exemplary embodiments of the present invention will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that although such a development effort might be complex and time consuming, it would nevertheless be a routine undertaking of design, fabrication, and manufacture for those of ordinary skill having the benefit of this disclosure.

As described above, connectivity tests on modern PCBs often involve driving test signals across the conductive interconnects that connect the integrated circuits on the PCB with one another. Specifically, a plurality of registers assemblies on each of the integrated circuits on the PCB may drive test signals between themselves to test the conductive interconnects that are supposed to connect the register assemblies (and hence the integrated circuits) to one another. These tests are often performed simultaneously for a plurality of integrated circuits disposed along an electrical path that may be referred to as a scan chain.

Due to their complexity, however, modern PCBs may have multiple scan chains that may run from one integrated circuit to another across one or more PCBs. Highly complex PCBs typically use integrated circuits with bi-directional registers assemblies to perform the connectivity tests. Use of these register assemblies, however, has potential disadvantages. In particular, if two registers assemblies on either side of one conductive interconnect are both driving a test signal across the same conductive interconnect, it can cause a drive fight and potentially damage the PCB or the integrated circuits.

One of the principal reasons that drive fights occur while testing a PCB is that multiple integrated circuits in multiple scan chains are involved in the interconnect test. Because test patterns are loaded and unloaded onto the scan chains sequentially, some finite amount of time will occur between the loading of any two scan chains. Thus, when a test pattern is being loaded, or when switching from one test pattern to another, the drivers located within two or more register assemblies connected to the same conductive interconnect may be active. One way to avoid these potential drive fights is to place the register assemblies into a neutral state between connectivity tests. Placing the register assemblies in a neutral state after each connectivity test prevents the drivers within the register assemblies from continuing to drive a signal in conflict with another connectivity test. This may prevent drive fights.

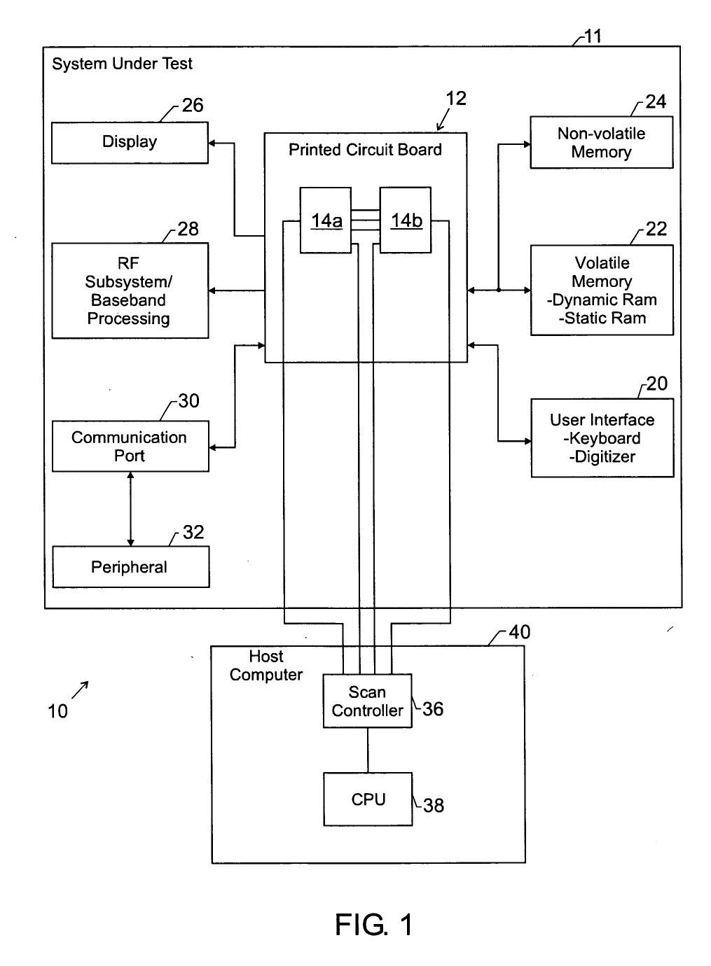

Turning now to FIG. 1, a block diagram depicting an exemplary system configured to perform connectivity tests in accordance with embodiments of the present invention is illustrated and generally designated by a reference numeral 10. The system 10 may comprise a system under test (SUT) 11 and a host computer 40. The SUT 11 be any of a variety of different types of devices, such as a computer, pager, cellular telephone, personal organizer, control circuit, etc. The SUT 11 typically includes a printed circuit board (PCB) 12. In one embodiment, the PCB 12 is a motherboard in a personal computer. In another embodiment, the PCB is located in a cellular phone or a personal digital assistant. In yet another embodiment, there may be multiple SUTs 11 or multiple PCBs 12.

The PCB 12 may comprise a first integrated circuit 14a and a second integrated circuit 14b. In one embodiment, the first integrated circuit 14a is a central processing unit, such as a Pentium 4 processor or an Athlon processor, and the second integrated circuit 14b is an application specific integrated circuit (“ASIC”). In another embodiment, both the first integrated circuit 14a and the second integrated circuit 14b are processors. In yet another embodiment, the integrated circuits 14a and 14b may be located within any of the components of the SUT 11. For example, the integrated circuits 14a and 14b may be memory circuits or communication circuits, as will be described in greater detail below. Those skilled in the art will appreciate that the embodiments described above are merely exemplary and are not intended to be exclusive.

Various other devices may also be coupled to the PCB 12, depending upon the functions that the SUT 11 performs. For instance, a user interface 20 may be coupled to the PCB 12. The user interface 20 may include an input device, such as buttons, switches, a keyboard, a light pen, a mouse, a fingerprint reader, and/or a voice recognition system, for instance. A display 26 may also be coupled to the PCB 12. The display 26 may include an LCD display, a CRT, LEDs, and/or an audio display. Furthermore, the RF subsystem/baseband processor 28 may also be coupled to the PCB 12. The RF subsystem/baseband processor 28 may include an antenna that is coupled to an RF receiver and to an RF transmitter (not shown). A communication port 30 may also be coupled to the PCB 12. The communication port 30 may be adapted to be coupled to a peripheral device 32, such as a modern, a printer, or another computer system, for instance, or to a network, such as a local area network or the Internet. As stated above, in certain embodiments, one or both of the integrated circuits 14a and 14b may be located within one or more of the above named components. For example, the integrated circuits 14a and 14b may be communication circuits located within the communication port 30. In this embodiment, a scan controller 36, which will described in greater detail below, may be coupled to the communication port 30.

The PCB 12 may also be coupled to the volatile memory 22, which may include dynamic random access memory (DRAM), static random access memory (SRAM), Double Data Rate (DDR) memory, etc. The PCB 12 may also be coupled to non-volatile memory 24. The non-volatile memory 24 may include a read only memory (ROM), such as an EPROM or Flash Memory, to be used in conjunction with the volatile memory. The size of the ROM is typically selected to be just large enough to store any necessary operating system, application programs, and fixed data. The volatile memory 22, on the other hand, is typically quite large so that it can store dynamically loaded applications. Additionally, the non-volatile memory 24 may include a high capacity memory such as a disk drive, tape drive memory, CD ROM drive, DVD, read/write CD ROM drive, and/or a floppy disk drive. As stated above, in certain embodiments, the integrated circuits 14a and 14b may be located within one or more of the above named components. For example, one or both of the integrated circuits 14a and 14b may be circuits located within the volatile memory 22 or the non-volatile memory 24. In this embodiment, the scan controller 36, which will be described in greater detail below, may be coupled to either the volatile memory 22 or the non-volatile memory 24, respectively.

The system 10 may also comprise the host computer 40. The host computer 40 may be coupled to the SUT 11 to perform a connectivity test on the SUT 11. The host computer may comprise the scan controller 36 and a central processing unit (CPU) 38. While not shown in FIG. 1, those skilled in the art will appreciate that the host computer 40 may also comprise those additional components, such as memory, a display, a keyboard, and any other components that are typically associated with a computer.

As stated above, the host computer 10 may be coupled to the SUT 11 to perform a connectivity test on the SUT 11. In particular, the scan controller 36 may be coupled to the PCB 12. In alternate embodiments the scan controller 36 may be coupled to any of the components within the SUT 11. In yet another embodiment, the scan controller 36 may be coupled to components residing on multiple SUTs 11. Further, in alternate embodiments, the scan controller 36 may be located inside the SUT 11. For example, the scan controller 36 and the CPU 38 may be located on the PCB 12 or on a daughter board coupled to the PCB 12. In these embodiments, the host computer 40 may not be present in the system 10 or the host computer 40 may be used to interact with the scan controller.

The scan controller 36 may comprise an integrated circuit, an application specific integrated circuit (ASIC), or any other suitable form of digital or analog circuit. The scan controller 36 may initiate and control connectivity tests on the PCB 12. In one embodiment, the scan controller receives commands from either the CPU 38 or a user and performs connectivity tests by transmitting test commands to the integrated circuits 14a and 14b. These test commands may place the integrated circuits 14a and 14b into a test mode or may direct the execution of the connectivity test. In one embodiment, the test commands may direct the integrated circuits 14a and 14b to place their register assemblies into a neutral state.

As will be described in greater detail below, the scan controller 36 may also command the integrated circuits 14a and 14b to transmit the results of the connectivity test back to the scan controller 36 for logging or for reporting to the user. As described above, the scan controller 36 typically operates under the command of a CPU 38 located in the host computer 40. In this case, the CPU 38 may control the connectivity test by issuing commands to the scan controller 36 and receiving reports from the scan controller 36. Those skilled in the art will appreciate that in alternate embodiments, the scan controller 36 may operate independently without the CPU 38.

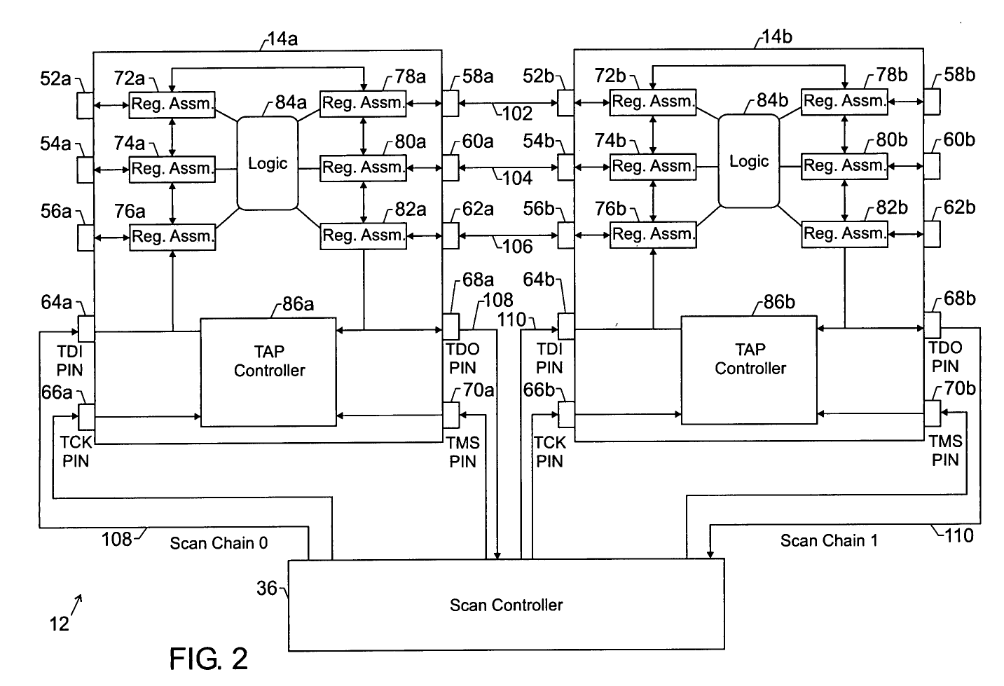

Turning next to FIG. 2, a block diagram of two exemplary integrated circuits 14a and 14b and a scan controller 36 configured to perform connectivity tests in accordance with embodiments of the present invention is illustrated. For simplicity, like reference numerals have been used to designate those features previously described in reference to FIG. 1.

Each of the integrated circuits 14a and 14b may comprise register assemblies 72a,b, 74a,b, 76a,b, 78a,b, 80a,b, and 82a,b. The register assemblies 72a,b, 74a,b, 76a,b, 78a,b, 80a,b, and 82a,b, which will be described in greater detail below, may be coupled to each other to form a chain of register assemblies disposed between input/output (“I/O”) pins 52a,b, 54a,b, 56a,b, 58a,b, 60a,b, and 62a,b and core logic 84a,b. In one embodiment, the register assemblies 72a,b, 74a,b, 76a,b, 78a,b, 80a,b, and 82a,b may comprise boundary scan registers that conform to the Institute of Electrical and Electronic Engineers (“IEEE”) Standard Test Access Port and Boundary Scan Architecture, which is also known as the 1149.1 standard. The IEEE 1149.1 standard is well known to those skilled in the art. However, briefly stated, the 1149.1 standard defines a methodology for performing integrated circuit and PCB testing using registers disposed at the inputs and outputs of the integrated circuits on a PCB.

As stated above, the register assemblies 72a,b, 74a,b, 76a,b, 78a,b, 80a,b, and 82a,b may be coupled to I/O pins 52a,b, 54a,b, 56a,b, 58a,b, 60a,b, and 62a,b respectively. The I/O pins 52a,b, 54a,b, 56a,b, 58a,b, 60a,b, and 62a,b, in turn, may be coupled to conductive interconnects, such as conductive interconnects 102, 104, and 106. In this way, the register assemblies 72a,b, 74a,b, 76a,b, 78a,b, 80a,b, and 82a,b located on one of the integrated circuits 14a and 14b may be coupled to register assemblies located on another one of the integrated circuits 14a and 14b or on an integrated circuit located elsewhere in the SUT 11 that was depicted in FIG. 1. While FIG. 2 only illustrates conductive interconnects 102, 104, and 106 for ease of illustration, those skilled in the art will appreciate that in alternate embodiments, there may be additional conductive interconnects coupled to the I/O pins 52a, 54a, 56a, 58b, 60b, and 62b.

The register assemblies 72a,b, 74a,b, 76a,b, 78a,b, 80a,b, and 82a,b may also be coupled to Test Access Port (“TAP”) controllers 86a and 86b, respectively. In one embodiment, the TAP controllers 86a and 86b are sixteen state machines that are capable of performing an interconnectivity test by controlling the register assemblies 72a,b, 74a,b, 76a,b, 78a,b, 80a,b, and 82a,b. The TAP controllers 86a and 86b may receive test commands from the scan controller 36 through test mode select pins 70 (hereafter referred to as the TMS pins 70). As will be described in greater detail below, the TAP controllers 86a,b may respond to commands from the scan controller 36 by transmitting a test pattern to the registers within register assemblies 72a,b, 74a,b, 76a,b, 78a,b, 80a,b, and 82a,b. The TAP controllers 86 may also direct the register assemblies 72a,b, 74a,b, 76a,b, 78a,b, 80a,b, and 82a,b to drive test pattern signals across the conductive interconnects 102, 104, and 106. The TAP controller 86 may also receive a test clock signal from the scan controller 36 through the test clock pins 66 (hereafter referred to as the TCK pins 66). In one embodiment, the TAP controllers 86a and 86b may conform with the IEEE 1149.1 standard.

The integrated circuits 14a and 14b may also comprise test data input pins 64a and 64b (hereafter referred to the TDI pins) and test data output pins 68a and 68b (hereafter referred to as the TDO pins). The TDI pins 64 and the TDO pins 68 may couple the TAP controllers 86 and the register assemblies 72a,b, 74a,b, 76a,b, 78a,b, 80a,b, and 82a,b to the scan controller 36. The electrical paths that proceed from the scan controller 36 to the TDI pins 64, through each of the register assemblies 72a,b, 74a,b, 76a,b, 78a,b, 80a,b, and 82a,b, through the TDO pins 68, and lastly back to the scan controller 36 are referred to as scan chains. The scan chain that runs through the integrated circuit 14a is referred to as scan chain 108 and the scan chain that runs through the integrated circuit 14b is referred to as scan chain 110. As will be described in further detail below, the scan controller 36 may employ the scan chains 108 and 110 to retrieve the results of the connectivity test.

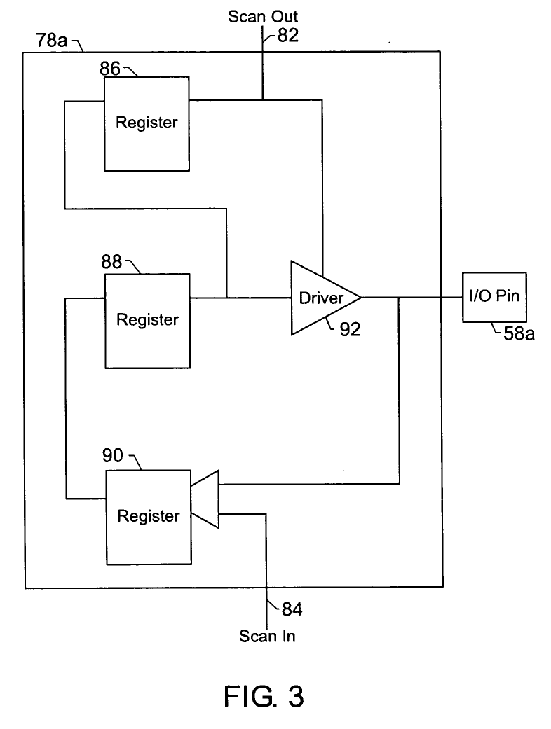

Turning now to FIG. 3, a block diagram illustrating the exemplary register assembly 78a and the I/O pin 58a configured to perform connectivity tests in accordance with embodiments of the present invention. For simplicity, like reference numerals have been used to designate those features previously described in reference to FIG. 2. Those skilled in the art will appreciate that while the register assembly and the I/O pin illustrated in FIG. 3 will be referred to as register assembly 78a and I/O pin 58a, the description of the register assembly 78a and the I/O pin 58a applies to the register assemblies, 72a,b, 74a,b, 76a,b, 78a,b, 80a,b, and 82a,b and I/O pins 52a,b, 54a,b, 56a,b, 58a,b, 60a,b, and 62a,b that were illustrated in FIG. 2.

The register assembly 78a comprises a driver control register 86, a test pattern register 88, a capture register 90, and a driver 92. The registers 86, 88, and 90 are illustrated in FIG. 1 as one-bit registers. In alternate embodiments, the registers 86, 88, and 90 may be larger than one bit registers. The driver 92 may drive a test signal across the I/O pin 58a and then across the conductive interconnect 102 illustrated in FIG. 2. Those skilled in that art will appreciate that the driver 92 may also be bi-directional and thus capable of receiving test signals in addition to transmitting test signals.

The driver control register 86 may control the driver 92. For example, if the register 86 is set as a logical “one,” the driver 92 may be configured to drive the test pattern signal, and if the register 86 is set to a logical “zero,” the driver 92 may be configured to not drive the test pattern signal. The test pattern register 88 may stored a test pattern and transmit the test pattern signal to the driver 92 for transmission across the conductive interconnect 102. The capture register 90 may capture test pattern signals that were driven across the conductive interconnect 102 from the integrated circuit 14b illustrated in FIG. 2. In alternate embodiments, the capture register 90 may be absent and the test pattern register may capture the test pattern signal.

The register assembly 78a may also comprise a “scan in” conductive interconnect 84 and a “scan out” conductive interconnect 82. The “scan in” conductive interconnect 84 may be coupled to the TDI pin 64a illustrated in FIG. 2 or to a “scan out” conductive interconnect in another register assembly that is upstream from the register assembly on the scan chain. For example, the “scan in” conductive interconnect 84 may be coupled to a “scan out” conductive interconnect in the register assembly 72a because the register assembly 72a is upstream from the register assembly 78a in the scan chain 108. Similarly, the “scan out” conductive interconnect may be coupled to the TDO pin 68a or to a “scan in” conductive interconnect on a register assembly downstream from the register assembly 78a.

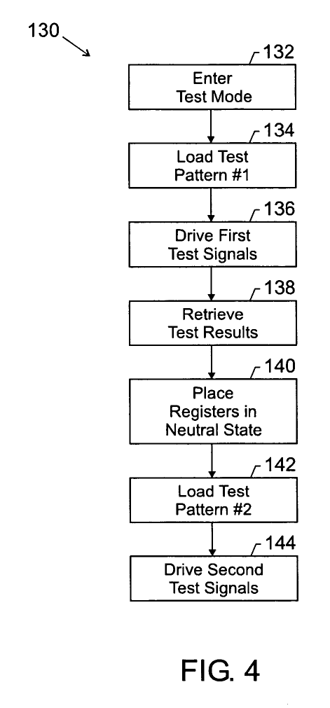

Turning now to FIG. 4, a flow chart illustrating an exemplary process for performing connectivity tests is illustrated and generally designated by a reference numeral 130. For ease of description, the process 140 will be described in relation to the embodiments depicted in FIGS. 2 and 3. While the process 130 is described in reference to the scan chain 108 and the scan chain 110, it will be appreciated by those skilled in the art that two scan chains are described for ease of description only. In alternate embodiments, there may be more or less than two scan chains. Further, in one embodiment, the connectivity tests may be performed in conformity with the IEEE 1149.1 standard.

As indicated by block 132, the connectivity test may begin with the integrated circuits 14a and 14b entering a test mode. While in the test mode, the core logic 84 of the integrated circuits 14a and 14b may be inactive. In non-testing applications, the core logic 84 typically performs the main function of the integrated circuit. For example, if the integrated circuit 14a is graphics processor, the core logic 84a may render graphics. Entering the test mode may improve the quality of the connectivity test by preventing the core logic 84 from interfering with the testing by acting on test signals as if they were instructions for it. It is important to note that the process 130 described below may be performed entirely in test mode. In one embodiment, entering the test mode may comprise entering an external boundary test mode as outlined in the IEEE 1149.1 standard. In this embodiment, the integrated circuits 14a and 14b may enter the external boundary test mode when the scan controller 36 transmits an EXTEST command to the TAP controllers 86a and 86b. In alternate embodiments, the register assemblies 72a,b, 74a,b, 76a,b, 78a,b, 80a,b, and 82a,b may place themselves in test mode in response to a command from the user, or the TAP controllers 86a and 86b may place the integrated circuits 14a and 14b in test mode.

Once the integrated circuits 14a and 14b enter the test mode, the connectivity test may continue by loading a first test pattern, as indicated by block 134. In one embodiment, the scan controller 36 may transmit the first test pattern to the TAP controllers 86a and 86b. The TAP controllers 86a and 86b may then set each of their respective register assemblies 72a,b, 74a,b, 76a,b, 78a,b, 80a,b, and 82a,b to match the first test pattern. For example, the connectivity test may comprise transmitting test signals from the integrated circuit 14b to the integrated circuit 14a. For this reason, the first test pattern may comprise loading digital “ones” in the test pattern registers within the register assemblies 72b, 74b, and 76b, wherein the test pattern registers within the register assemblies 72a,b, 74a,b, 76a,b, 78a,b, 80a,b, and 82a,b may begin loaded with “zeros.” Those skilled the art will appreciate that this is only one embodiment of the first test pattern. In alternate embodiments, the first test pattern may differ. Further, in alternate embodiments, the test pattern may be stored elsewhere within system 10 depicted in FIG. 1.

After the first test pattern has been loaded into the register assemblies 72a,b, 74a,b, 76a,b, 78a,b, 80a,b, and 82a,b, the TAP controllers 86a and 86b may direct the register assemblies 72a,b, 74a,b, 76a,b, 78a,b, 80a,b, and 82a,b to either drive the first test pattern signals across the conductive interconnects 102, 104, and 106 or to receive the first test pattern signals. Specifically in the case of the first test pattern, this may comprise transmitting the “ones” stored in the register assemblies 72b, 74b, and 76b across the conductive interconnects 102, 104, and 106 to the register assemblies 78a, 80a, and 82a. If the conductive interconnects 102, 104, and 106 are functioning properly, these “ones” will be transmitted from the registers 72b, 74b, and 76b to the registers 78a, 80a, and 82a. In this case, the registers 78a, 80a, and 82a may capture a “one.” If, however, a particular one of the conductive interconnects 102, 104, and 106 has an open circuit or is shorted to ground or to another conductive interconnect, the register assembly 78a, 80a, and 82a coupled to that malfunctioning conductive interconnect may not capture a one. In this way, the scan controller 36 or the CPU 38 may be able to determine the status of each of the conductive interconnects 102, 104, and 106 by comparing the pattern of “ones” and “zeros” captured in the register assemblies 78a, 80a, and 82a (i.e., the first test pattern) with the pattern of “ones” and “zeros” stored in the registers 72b, 74b, and 76b. If the two patterns match, it may indicate that all of the conductive interconnects 102, 104, and 106 are functioning properly.

In one embodiment, one of the register assemblies 72b, 74b, and 76b may be set as a “zero” to test whether one of the conductive interconnects 102, 104, and 106 is improperly connected to a logic ‘one’ source. In this case, if any one of the register assemblies 78a, 80a, and 82a on the other side of the conductive interconnect 102, 104, and 106 contains a “one” after the connectivity test it may indicate that the conductive interconnect 102, 104, and 106 may be improperly connected.

As described above, after the register assemblies 72b, 74b, and 76b have driven the first test pattern signals, the “results” of the connectivity test may be captured in the register assemblies 78a, 80a, and 82a. In one embodiment, the scan controller 36 may retrieve the “results” by transmitting a test retrieval signal along the scan chain 108, as indicated by block 138 in FIG. 4. In particular, the scan controller 36 may transmit a TMS signal via the TMS pin 70a to command the TAP controller 86a to activate a shift mode on the scan chain 108. The test results may then be shifted through each of the registers 72a-82a and then transmitted back to the scan controller 36 via the TDO pin 68a. If the “results” embodied by the test retrieval signal match the first test pattern that was stored in the register assemblies 72b, 74b, and 76b, then the host computer 40 depicted in FIG. 1 may determine that the conductive interconnects 102, 104, and 106 are functioning properly. If the captured “results” do not match the first test pattern, the host computer 40 may log an error or notify the user that there is a potential problem with one of the conductive interconnects 102, 104, and 106.

As described above, modern PCBs typically comprise multiple scan chains. For this reason, after completing one connectivity test, the scan controller 36 may be programmed to perform an additional connectivity test. However, in this connectivity test register assemblies 58a, 60a, and 62a may be driving the interconnect under test while register assemblies 72b, 74b, and 76b may capture the results of the test.

Before performing a subsequent connectivity test however, register assemblies 72a,b, 74a,b, 76a,b, 78a,b, 80a,b, and 82a,b may be placed in a neutral state, as indicated by block 140 in FIG. 4. Placing the register assemblies 72a,b, 74a,b, 76a,b, 78a,b, 80a,b, and 82a,b into a neutral state may comprise disabling the drivers within the register assemblies 72b, 74b, and 76b. Recall from above, that during the connectivity test on the scan chain 108, the register assemblies 72b, 74b, and 76b drove the first test pattern signals onto the conductive interconnects 102, 104, and 106. If a subsequent connectivity test involves driving signals from register assemblies 78a, 80a, and 82a to register assemblies 72b, 74b, and 76b, then a drive fight might occur if one of the register assemblies 72b, 74b, and 76b is still driving the first test pattern signal when the subsequent connectivity test begins.

To prevent this drive fight from occurring, in one embodiment, the scan controller 36 may place the register assemblies 72a,b, 74a,b, 76a,b, 78a,b, 80a,b, and 82a,b in a neutral state by sending a command to the integrated circuits 14a and 14b to place the registers to disable the drivers within the register assemblies 72a,b, 74a,b, 76a,b, 78a,b, 80a,b, and 82a,b. Disabling the drivers may comprise loading a logical “zero” in the driver control registers within the register assemblies 72a,b, 74a,b, 76a,b, 78a,b, 80a,b, and 82a,b. In one embodiment, disabling the drivers within the register assemblies 72a,b, 74a,b, 76a,b, 78a,b, 80a,b, and 82a,b may be referred to as tri-stating the register 72a,b, 74a,b, 76a,b, 78a,b, 80a,b, and 82a,b. In alternate embodiments, the drivers within the register assemblies may be disabled in alternative ways, including placing the register assemblies 72a,b, 74a,b, 76a,b, 78a,b, 80a,b, and 82a,b into a receiving state. Further, those skilled in the art will appreciate that the embodiments described above are merely exemplary and are not intended to be exclusive. Further, in one embodiment, placing the register assemblies 72a,b, 74a,b, 76a,b, 78a,b, 80a,b, and 82a,b in a neutral state comprises only placing the register assemblies that were driving the first test pattern (i.e., the register assemblies 52b, 54b, and 56b) in a neutral state.

After the register assemblies 72a,b, 74a,b, 76a,b, 78a,b, 80a,b, and 82a,b have been placed in a neutral state, the scan controller 36 may load a second test pattern and direct the TAP controllers 86a and 86b to drive the second test pattern across the conductive interconnects 102, 104, and 106, as indicated in blocks 142 and 144 of FIG. 4. This second connectivity test (along the scan chain 110) may be performed in the same manner as the first connectivity test except that the second test pattern may be used instead of the first test pattern. For example, the second connectivity test may comprise placing logical “ones” in the test pattern registers of the register assemblies 78a, 80a, and 82a and then driving those “ones” across the conductive interconnects 102, 104, and 106 to the register assemblies 72b, 74b, and 76b. As described above, those skilled in the art will appreciate that the scan chain 110 is illustrated as comprising only the integrated circuit 14b for strictly illustrative purposes. In alternate embodiments, the scan chain 110 may comprises numerous integrated circuits.

The technique described above, which may be implemented in hardware, in firmware, in software, in an ASIC, or in a combination of these, comprise a listing of executable instructions for implementing logical functions. The listing can be embodied in any device readable medium suitable for use by or in connection with a computer-based system that can retrieve the instructions and execute them. In the context of this application, the computer-readable medium can be any means that can contain, store, communicate, propagate, transmit, or transport the instructions. The readable medium can be an electronic, a magnetic, an optical, an electromagnetic, or an infrared system, apparatus, or device. An illustrative, but non-exhaustive list of readable mediums can include an electrical connection having one or more wires, a portable computer diskette, a random access memory (RAM), a read-only memory (ROM), an erasable programmable read-only memory (such as EPROM or Flash memory), an optical fiber, and a portable compact disc read-only memory (CDROM). For instance, the instructions can be electronically captured via optical scanning of the paper or other medium, then compiled, interpreted, or otherwise processed in a suitable manner if necessary, and then stored in a memory.

While the invention may be susceptible to various modifications and alternative forms, specific embodiments have been shown by way of example in the drawings and will be described in detail herein. However, it should be understood that the invention is not intended to be limited to the particular forms disclosed. Rather, the invention is to cover all modifications, equivalents, and alternatives falling within the spirit and scope of the invention as defined by the following appended claims.

What is claimed is:

1. A method of testing a printed circuit board comprising:
placing a first integrated circuit into a test mode, wherein the first integrated circuit is coupled to a conductive interconnect;
causing a register assembly located on the first integrated circuit to transmit a test signal onto the conductive interconnect; and
placing the register assembly into a neutral state, wherein the first integrated circuit is placed into the neutral state without exiting the test mode.

2. The method, as set forth in claim 1, wherein placing the first integrated circuit into the test mode comprises placing the first integrated circuit into an external boundary test mode.

3. The method, as set forth in claim 2, wherein placing the first integrated circuit into the external boundary test mode comprises transmitting an EXTEST signal from a scan controller to a test access port controller located on the first integrated circuit.

4. The method, as set forth in claim 1, wherein placing the register assembly into the neutral state comprises disabling a driver within the register assembly.

5. The method, as set forth in claim 4, wherein disabling the driver within the register assembly comprises loading a logical “zero” into a driver control register located in the register assembly.

6. The method, as set forth in claim 1, wherein placing the register assembly into the neutral state comprises placing the register assembly into a receiving state.

7. The method, as set forth in claim 1, comprising:
placing a second integrated circuit into the test mode, wherein the second integrated circuit is coupled to the conductive interconnect; and
receiving the test signal at a register assembly located on the second integrated circuit.

8. The method, as set forth in claim 7, comprising:
comparing the test signal received by the register assembly located on the second integrated circuit with the test signal transmitted by the register assembly on the first integrated circuit.

9. The method, as set forth in claim 7, wherein placing a second integrated circuit into test mode comprises placing the second integrated into test mode, wherein the second integrated circuit is located on a different scan chain than the first integrated circuit.

10. A device comprising:
a scan controller configured to be coupled to an integrated circuit and configured to perform a connectivity test on the integrated circuit by transmitting a command signal to the integrated circuit, wherein the command signal:
places the integrated circuit into a test mode;
causes a register assembly located on the integrated circuit to drive a test signal onto a conductive interconnect; and
places the register assembly into a neutral state, wherein the integrated circuit is placed in a neutral state without the integrated circuit exiting the test mode.

11. The device, as set forth in claim 10, comprising a central processing unit configured to send a signal to the scan controller to initiate the connectivity test on the integrated circuit.

12. The device, as set forth in claim 10, comprising a display.

13. The device, as set forth in claim 10, wherein the device comprises the integrated circuit.

14. The device, as set forth in claim 10, wherein the command signal that places the register assembly into the neutral state comprises the command signal that directs the integrated circuit to load a logical “zero” into a driver control register.

15. The device, as set forth in claim 10, wherein the command signal that places the register assembly into the neutral state comprises the command signal that directs the integrated circuit to place the register assembly into a receiving state.

16. The device, as set forth in claim 10, wherein the scan controller is located on a daughter board and the integrated circuit is located on a motherboard.

17. The device, as set forth in claim 10, wherein the register assembly comprises a boundary scan register conforming to I.E.E.E. 1149.1.

18. A method of testing an electronic device comprising:
performing a first connectivity test on a trace in accordance with IEEE 1149.1, wherein the trace is disposed between two integrated circuits;
placing the trace into a neutral state, wherein the placing the trace into a neutral state does not involve the two integrated circuits exiting external boundary test mode; and
performing a second connectivity test on the trace in accordance with IEEE 1149.1.

19. The method as set forth in claim 18, wherein placing the trace into a neutral state comprises disabling a driver coupled to the trace.

20. A method of performing a connectivity test comprising:
entering a test mode;
loading a first test pattern into a first integrated circuit;
driving a first test signal from the first integrated circuit to a second integrated circuit; and
placing the first integrated circuit and the second integrated circuit in a neutral state.

21. The method, as set forth in claim 20, comprising retrieving test results from the first integrated circuit.

22. The method, as set forth in claim 21, comprising loading a second test pattern into the second integrated circuit;

23. The method, as set forth in claim 22, comprising driving a second test signal from the second integrated circuit to the first integrated circuit.

24. A system for performing a connectivity test comprising:
a first integrated circuit configured to operate in a test mode;
a second integrated circuit coupled to the first integrated circuit by a conductive interconnect and configured to operate in the test mode; and
a scan controller configured to perform two connectivity tests involving the conductive interconnect, wherein the first integrated circuit is configured to place the conductive interconnect in a neutral state between the two connectivity tests without either the first integrated circuit or the second integrated circuit exiting the test mode.

25. The computer system, as set forth in claim 24, wherein the first integrated circuit and the second integrated circuit are located on different printed circuit boards.

26. The computer system, as set forth in claim 24, wherein the first integrated circuit is processor.

27. The computer system, as set forth in claim 24, wherein the first integrated circuit is memory chip.

28. The computer system, as set forth in claim 24, wherein the first integrated circuit is an application specific integrated circuit.

29. The system, as set forth in claim 24, comprising a display unit.

30. A tangible medium storing instructions to be run on a computer, the instructions comprising:
code adapted to place a first integrated circuit into a test mode, wherein the first integrated circuit is coupled to a conductive interconnect;
code adapted to cause a register assembly located on the first integrated circuit to transmit a test signal onto the conductive interconnect; and
code adapted to place the register assembly into a neutral state, wherein the first integrated circuit is placed into the neutral state without the first integrated circuit exiting test mode.

31. A system for performing a connectivity test comprising:
means for entering a test mode;
means for loading a first test pattern into a first integrated circuit;
means for driving a first test signal from the first integrated circuit to a second integrated circuit; and
means for placing the first integrated circuit and the second integrated circuit in a neutral state.

32. The system, as set forth in claim 31, comprising means for loading a second test pattern into the second integrated circuit.

33. The system, as set forth in claim 32, comprising means for driving a second test signal from the second integrated circuit to the first integrated circuit.
